(19) United States
(12) Patent Application Publication
(10) Pub. No.: US 2011/0245064 A1
(43) Pub. Date: Oct. 6, 2011

(54) NON-SINTERED METAL-INSULATOR-METAL CAPACITOR AND METHOD OF MANUFACTURING THE SAME

(75) Inventors: Ji-Hoon Kim, Seoul (KR); Jong-Hee Kim, Seoul (KR); Young-Jun Yoon, Gyeonggi-Do (KR); Hyo-Tae Kim, Gyeonggi-Do (KR); Jong-Woo Im, Seoul (KR)

(73) Assignees: JONG-WOO IM, SEOUL (KR); KOREA INSTITUTE OF CERAMIC ENGINEERING AND TECHNOLOGY, SEOUL (KR)

(21) Appl. No.: 12/776,854

(22) Filed: May 10, 2010

(30) Foreign Application Priority Data
Apr. 6, 2010 (KR) 10-2010-0031580

(51) Int. Cl. C04B 35/468; C04B 35/00; H01L 21/02

(52) U.S. Cl. 501/134; 438/381; 257/E21.008

(57) ABSTRACT

The present disclosure relates to a non-sintering metal-insulator-metal (MIM) capacitor and a method of manufacturing the same. The method of manufacturing a non-sintered MIM capacitor includes manufacturing a lower metal-insulator-upper metal structure, wherein the insulator is formed by a non-sintering process comprising: preparing a ceramic-polymer composition comprising a highly dielectric ceramic powder, a polymer resin, and a solvent, the highly dielectric ceramic powder comprising small powder and large powder having a larger average particle size than the small powder; forming a ceramic-polymer film by depositing the ceramic-polymer composition on the lower metal; and curing the polymer resin in the ceramic-polymer film.

### BACKGROUND OF THE INVENTION

1. Field of the Invention

The present invention relates to metal-insulator-metal (MIM) capacitors including a lower metal-insulator-upper metal structure. More particularly, the present invention relates to a technique for manufacturing a non-sintered MIM capacitor which has a high dielectric constant and can reduce manufacturing costs while solving a problem of volume shrinkage.

2. Description of the Related Art

A metal-insulator-metal (MIM) capacitor includes two metals consisting of an upper metal and a lower metal, and an insulator interposed therebetween.

For good performance, the MIM capacitor must have a good electric charge storage capacity at an interface between the metal and the insulator, which can be ensured by increasing a dielectric constant of the insulator.

In a conventional method of forming an insulator for the MIM capacitor, a film is formed on the metal or between the metals using a paste containing highly dielectric ceramic powder and an organic or inorganic binder, and is then subjected to sintering.

However, sintering inevitably entailed in the conventional method causes an increase in manufacturing cost, volume shrinkage, and embrittlement of ceramic.

### SUMMARY OF THE INVENTION

The present invention is conceived to solve the above problems, and an aspect of the invention is to provide a method of manufacturing a non-sintered MIM capacitor, which includes a process of forming an insulator in a non-sintering manner in formation of an MIM capacitor including a lower metal-insulator-upper metal structure.

Another aspect of the present invention is to provide a non-sintered MIM capacitor which has a high dielectric constant and can reduce manufacturing costs while solving a problem of volume shrinkage, which is caused by the conventional MIM manufacturing method.

In accordance with an aspect, the present invention provides a method of manufacturing a non-sintered MIM capacitor, including manufacturing a lower metal-insulator-upper metal structure, wherein the insulator is formed by a non-sintering process comprising: preparing a ceramic-polymer composition comprising a highly dielectric ceramic powder, a polymer resin, and a solvent, the highly dielectric ceramic powder comprising small powder and large powder having a larger average particle size than the small powder; forming a ceramic-polymer film by depositing the ceramic-polymer composition on the lower metal; and curing the polymer resin in the ceramic-polymer film.

In accordance with another aspect, the present invention provides a method of manufacturing a non-sintered MIM capacitor, including manufacturing a lower metal-insulator-upper metal structure, wherein the insulator is formed by a non-sintering process comprising: preparing a ceramic composition comprising a highly dielectric ceramic powder and a solvent, the highly dielectric ceramic powder comprising small powder and large powder having a larger average particle size than the small powder; preparing a polymer composition comprising a polymer resin and a solvent; forming a ceramic film by depositing the ceramic composition on the lower metal; forming a ceramic-polymer film by depositing the polymer composition on the ceramic film and penetrating the polymer composition into the ceramic film; and curing the polymer resin in the ceramic-polymer film.

In accordance with a further aspect, the present invention provides a method of manufacturing a non-sintered MIM capacitor, including manufacturing a lower metal-insulator-upper metal structure, wherein the insulator is formed by a non-sintering process comprising: preparing a ceramic-polymer composition comprising a highly dielectric ceramic powder, a polymer resin, and a solvent, the highly dielectric ceramic powder having an average particle size of 400 nm˜800 nm; forming a ceramic-polymer film by depositing the ceramic-polymer composition on the lower metal; and curing the polymer resin in the ceramic-polymer film.

In accordance with yet another aspect, the present invention provides a method of manufacturing a non-sintered MIM capacitor, including manufacturing a lower metal-insulator-upper metal structure, wherein the insulator is formed by a non-sintering process comprising: preparing a ceramic composition comprising a highly dielectric ceramic powder and a solvent, the highly dielectric ceramic powder having an average particle size of 400 nm˜800 nm; preparing a polymer composition comprising a polymer resin and a solvent; forming a ceramic film by depositing the ceramic composition on the lower metal; forming a ceramic-polymer film by depositing the polymer composition on the ceramic film and penetrating the polymer composition into the ceramic film; and curing the polymer resin in the ceramic-polymer film.

In accordance with yet another aspect, the present invention provides a non-sintered MIM capacitor including a lower metal-insulator-upper metal structure, wherein the insulator is formed of a highly dielectric ceramic powder having a polymer resin impregnated therein, the highly dielectric ceramic powder comprising small powder and large powder having a larger average particle size than the small powder.

In accordance with yet another aspect, the present invention provides a non-sintered MIM capacitor including a lower metal-insulator-upper metal structure, wherein the insulator is formed of a highly dielectric ceramic powder having a polymer resin impregnated therein, the highly dielectric ceramic powder having an average particle size of 400 nm˜800 nm.

### BRIEF DESCRIPTION OF THE DRAWINGS

FIG. 1 is a flowchart of a method of manufacturing a non-sintered MIM capacitor in accordance with one embodiment of the present invention;

FIG. 2 is a flowchart of a method of manufacturing a non-sintered MIM capacitor in accordance with another embodiment of the present invention;

FIG. 3 is a graph depicting the variation of a packing density depending on the size of a highly dielectric ceramic powder;

FIG. 4 is a graph depicting the variation of a dielectric constant depending on the size of the highly dielectric ceramic powder;

FIG. 5 is a graph depicting the variation of a packing density depending on a volume fraction of small powder and large powder in the highly dielectric ceramic powder;

FIG. 6 is a graph depicting the variation of the dielectric constant depending on a volume fraction of small powder and large powder in the highly dielectric ceramic powder;

FIG. 7 is a graph depicting the variation of the packing density depending on a difference in average particle size of small powder and large powder in the highly dielectric ceramic powder;

FIG. 8 is a graph depicting the variation of the dielectric constant depending on a difference in average particle size of small powder and large powder in the highly dielectric ceramic powder;

FIG. 9 is a micrograph of an insulator of an MIM capacitor manufactured using only large powder having an average particle size of 150 nm as the highly dielectric ceramic powder;

FIG. 10 is a micrograph of an insulator of an MIM capacitor manufactured using 75 vol % of large powder having an average particle size of 150 nm and 25 vol % of small powder having an average particle size of 30 nm as the highly dielectric ceramic powder;

FIG. 11 is a micrograph of an insulator of an MIM capacitor manufactured using only large powder having an average particle size of 300 nm as the highly dielectric ceramic powder;

FIG. 12 is a micrograph of an insulator of an MIM capacitor manufactured using 75 vol % of large powder having an average particle size of 300 nm and 25 vol % of small powder having an average particle size of 30 nm as the highly dielectric ceramic powder;

FIG. 13 is a micrograph of an insulator of an MIM capacitor manufactured using only large powder having an average particle size of 500 nm as the highly dielectric ceramic powder; and

FIG. 14 is a micrograph of an insulator of an MIM capacitor manufactured using 75 vol % of large powder having an average particle size of 500 nm and 25 vol % of small powder having an average particle size of 30 nm.

### DETAILED DESCRIPTION OF THE EMBODIMENTS

The above and other aspects and features of the invention will become apparent from the following embodiments described in conjunction with the accompanying drawings. However, it should be understood that the invention is not limited to the following embodiments and may be embodied in different ways, and that the embodiments are given to provide complete disclosure of the invention and to provide thorough understanding of the invention to those skilled in the art. The scope of the invention is limited only by the accompanying claims and equivalents thereof. Like elements are denoted by like reference numerals throughout the specification.

Embodiments of the invention will now be described in detail with reference to the accompanying drawings.

The present invention relates to metal-insulator-metal (MIM) capacitors including a lower metal-insulator-upper metal structure. A method of manufacturing an MIM capacitor according to the invention may generally include processes, such as deposition of a lower metal, formation of an insulator, deposition of an upper metal, and the like, which are well known in the art of manufacture of the MIM capacitors. Herein, a method of forming the insulator interposed between the lower metal and the upper metal and determining performance of the MIM capacitor will be mainly described.

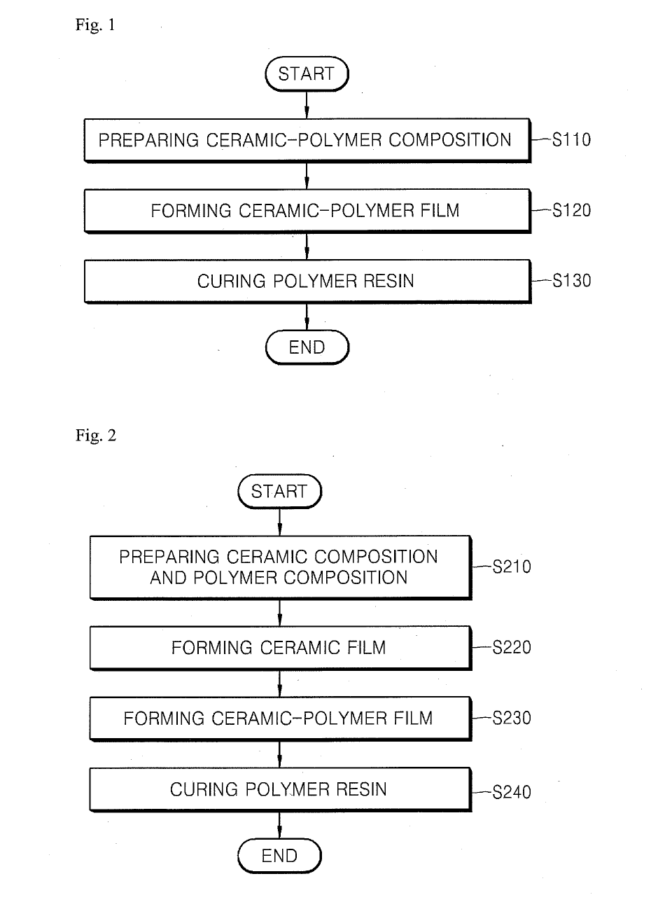

FIG. 1 is a flowchart of a method of manufacturing a non-sintered MIM capacitor in accordance with one embodiment of the invention. More specifically, FIG. 1 shows an embodiment in which a highly dielectric ceramic powder and a polymer resin are deposited together to form an insulator of the MIM capacitor.

Referring to FIG. 1, in the method of manufacturing the non-sintered MIM capacitor, the insulator is formed by preparing a ceramic-polymer composition in S110, forming a ceramic-polymer film in S120, and curing a polymer resin in S130.

In the preparation of the ceramic-polymer composition (S110), the ceramic-polymer composition comprises a highly dielectric ceramic powder, a polymer resin, and a solvent.

In this invention, an essential material for the insulator to be interposed between the lower metal and the upper metal is the highly dielectric ceramic powder. An example of the highly dielectric ceramic powder includes BaTiO₃.

In the MIM capacitor, the dielectric constant of the insulator is closely related to the average particle size of the highly dielectric ceramic powder.

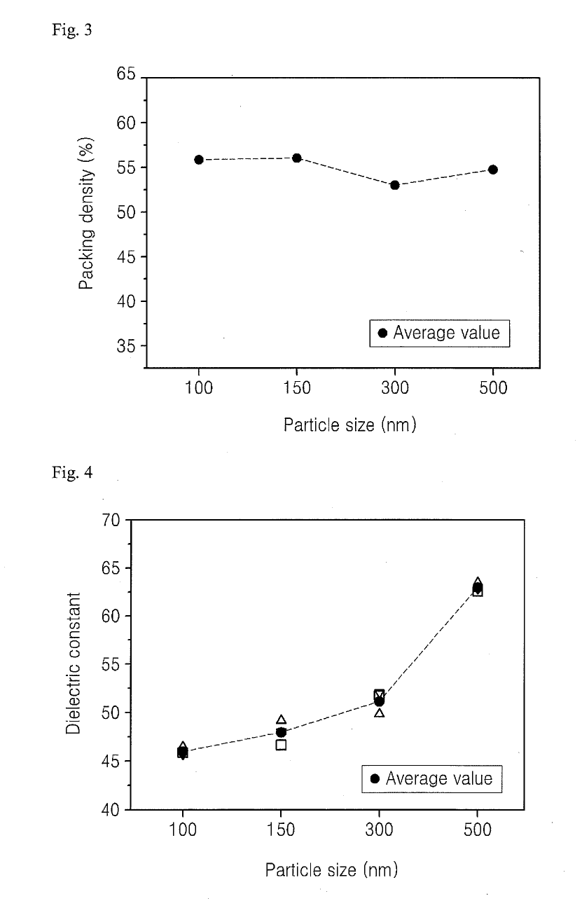

Referring to FIGS. 3 and 4, test results show that the dielectric constant of the insulator also increases as the average particle size of the highly dielectric ceramic powder increases. Thus, the highly dielectric ceramic powder may have a relatively large average particle size of about 400 nm or more. However, since an excessively large average particle size of the highly dielectric ceramic powder can lead to a difficulty in application of ink jet printing, the highly dielectric ceramic powder may comprise large powder having an average particle size in the range of about 400˜800 nm.

On the other hand, the highly dielectric ceramic powder may comprise small powder and large powder having a larger average particle size than the small powder.

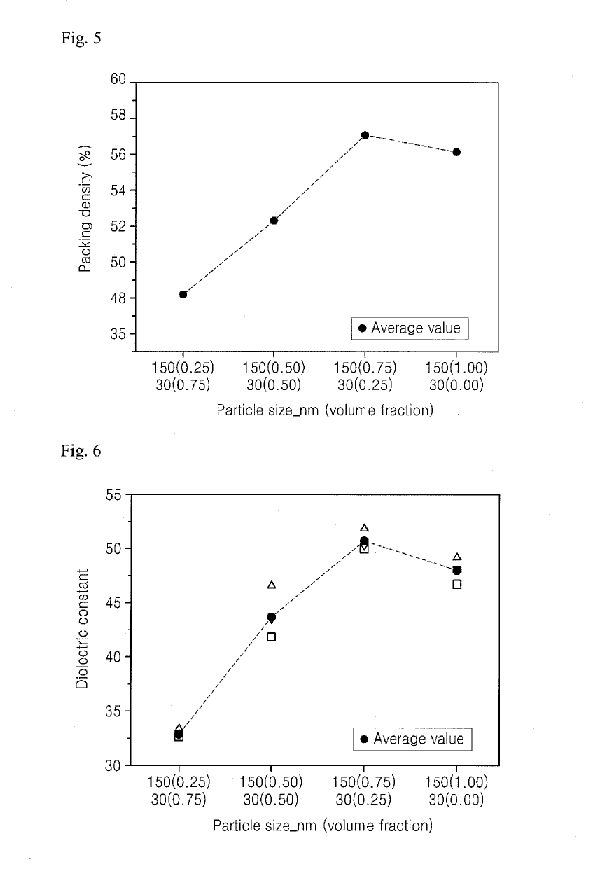

Referring to FIGS. 5 and 6, test results show that, as compared with the highly dielectric ceramic powder consisting of the small powder or the large powder, the highly dielectric ceramic powder comprising both the small powder and the larger powder has a higher packing density and a higher dielectric constant, thereby improving performance of the MIM capacitor.

The polymer resin is impregnated in a void between the highly dielectric ceramic particles. The polymer resin releases inherent brittleness of the ceramic by reducing stress of the highly dielectric ceramic powder. Examples of the polymer resin include, but are not limited to, polyacrylic resins, epoxy resins, phenolic resins, polyamide resins, polyimide resins, non-saturated polyester resins, and the like. Additionally, a thermocurable resin or a photocurable resin may be used as the polymer resin without limitation.

In the ceramic-polymer composition, the polymer resin may be contained in an amount of 10˜150 parts by weight with respect to 100 parts by weight of the highly dielectric ceramic powder. If the amount of polymer resin is less than 10 parts by weight, the effect of polymer impregnation becomes insufficient. On the contrary, if the amount of polymer resin exceeds 150 parts by weight, the MIM capacitor undergoes a reduction in dielectric characteristics of the insulator.

Examples of the solvent for the ceramic-polymer composition include water, ethanol, acetone, and formaldehyde, but are not limited thereto as long as the selected solvent is able to disperse the highly dielectric ceramic powder and the polymer resin.

Further, the ceramic-polymer composition may further comprise a dispersant for controlling surface tension and enhancing dispersibility. Examples of the dispersant include a non-ionic surfactant, an anionic surfactant, a cationic surfactant, octyl-alcohol and acrylic polymer, and the like. These compositions may be used alone or in a combination of two or more thereof.

If the dispersant is excessively added in the composition, it can deteriorate solution stability and the dielectric characteristics of the insulator in the MIM capacitor. Thus, the dispersant may be added in an amount of 5 parts by weight or less with respect to 100 parts by weight of the ceramic-polymer composition.

Next, in the formation of the ceramic-polymer film (S120), the ceramic-polymer composition is deposited and dried on the lower metal to form the ceramic-polymer film.

Here, the ceramic-polymer composition may be deposited thereon by ink-jet printing, which permits uniform deposition of the composition.

Next, in curing the polymer resin (S130), the polymer resin contained in the ceramic-polymer film is cured by applying heat or ultraviolet light to the film, thereby finally forming the insulator of the MIM capacitor.

With the combined structure of the highly dielectric ceramic powder and the polymer resin, the insulator of the MIM capacitor can be formed without sintering, that is, in a non-sintering manner. As a result, it is possible to reduce overall manufacturing costs.

Particularly, the insulator is formed in the non-sintering manner, so that shrinkage of the insulator caused by sintering can be overcome, thereby improving reliability in performance of the MIM capacitor.

FIG. 2 is a flowchart of a method of manufacturing a non-sintered MIM capacitor in accordance with another embodiment of the present invention.

Referring to FIG. 2, in the method of manufacturing the non-sintered MIM capacitor, an insulator is formed by preparing a ceramic composition and a polymer composition in S210, forming a ceramic film in S220, forming a ceramic-polymer film in S230, and curing a polymer resin in S240.

The MIM capacitor manufacturing method shown in FIG. 2 is similar to the method shown in FIG. 1. In the method shown in FIG. 1, both the highly dielectric ceramic and the polymer resin are deposited together. On the contrary, in the method shown in FIG. 2, after the ceramic film is formed on the lower metal by depositing a ceramic composition thereon, a polymer composition is deposited on the ceramic film and penetrates into the ceramic film.

In the preparation of the ceramic composition and the polymer composition (S210), the ceramic composition comprises a highly dielectric ceramic powder and a solvent. Here, the highly dielectric ceramic powder may comprise small powder and large powder having a larger average particle size than the small powder. Further, the highly dielectric ceramic powder may have an average particle size in the range of about 400˜800 nm.

Further, the polymer composition may comprise a polymer resin and a solvent.

Since such a ceramic composition and a polymer composition are prepared by separating the ceramic-polymer composition of FIG. 1, details thereof are substantially the same as those of the embodiment shown in FIG. 1.

In other words, the highly dielectric ceramic powder of the ceramic composition may comprise BaTiO₃. Further, in the polymer composition, a thermocurable resin or a photocurable resin may be used as the polymer resin without limitation. Examples of the solvent for each of the compositions include water, ethanol, and the like. Each of the compositions may further comprise a dispersant, such as a non-ionic surfactant, an anionic surfactant, a cationic surfactant, octyl-alcohol and acrylic polymer, and the like.

Further, the polymer resin may be contained in an amount of 10˜150 parts by weight with respect to 100 parts by weight of the highly dielectric ceramic powder. In this embodiment, the highly dielectric ceramic powder is contained in the ceramic composition and the polymer resin is contained in the polymer composition in the amounts of these ranges, respectively.

The ceramic composition or the polymer composition may be deposited by ink-jet printing.

In the formation of the ceramic film (S220), the ceramic composition is deposited on the lower metal to form the ceramic film.

In the formation of the ceramic-polymer film (S230), the polymer composition is deposited on the ceramic film formed on the lower metal, and penetrated into the ceramic film to form the ceramic-polymer film.

In curing the polymer resin (S240), the polymer resin in the ceramic-polymer film is cured to form the insulator of the MIM capacitor in the non-sintering manner.

FIG. 3 is a graph depicting the variation of a packing density depending on the size of the highly dielectric ceramic powder. FIG. 4 is a graph depicting the variation of a dielectric constant depending on the size of the highly dielectric ceramic powder.

Referring to FIG. 3, the variation of the packing density depending on the size of the highly dielectric ceramic powder (BaTiO₃) is not significant. However, referring to FIG. 4, it can be seen that as the average particle size of the highly dielectric ceramic powder increases, the dielectric constant also increases. When the highly dielectric ceramic powder has an average particle size of 500 nm, the insulator has an average dielectric constant of about 63. On the contrary, when the highly dielectric ceramic powder has an average particle size of about 400 nm, the insulator has an average dielectric constant of about 60. Thus, the highly dielectric ceramic powder having an average particle size of 400 nm or more may be advantageously applied to the insulator of the MIM capacitor.

FIG. 5 is a graph depicting the variation of the packing density depending on a volume fraction of small powder and large powder in the highly dielectric ceramic powder. FIG. 6 is a graph depicting the variation of the dielectric constant depending on a volume fraction of small powder and large powder in the highly dielectric ceramic powder.

Referring to FIGS. 5 and 6, it can be seen that as the volume fraction of the large powder increases, the packing density and the dielectric constant generally increase. Particularly, when the volume fraction of the large powder having an average particle size of 150 nm is about 0.75 (75 vol %) and the volume fraction of the small powder having an average particle size of 30 nm is about 0.25 (25 vol %), the insulator exhibits the highest dielectric constant.

As compared with the case where the large powder or the small powder is used alone in the insulator, the highly dielectric ceramic powder comprising about 70˜80 vol % of the large powder and 20˜30 vol % of the small powder may exhibit good dielectric characteristics for the insulator of the MIM capacitor.

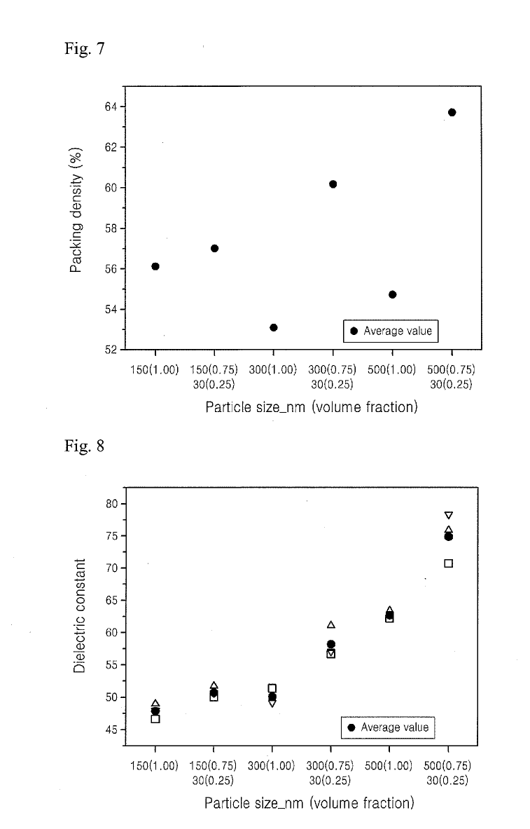

FIG. 7 is a graph depicting the variation of the packing density depending on a difference in average particle size of small powder and large powder in the highly dielectric ceramic powder. FIG. 8 is a graph depicting the variation of the dielectric constant depending on a difference in average particle size of small powder and large powder in the highly dielectric ceramic powder.

In theory, assuming the large powders have a complete close packed structure, a regular triangle is formed when connecting the centers of three large powders adjoining to one another on a plane. Thus, according to the Pythagorean Theorem, voids between the large particles can be filled with the small powders when the average particle size of the large powder is about 6.5 times or more that of the small powder.

In other words, in the case of using the large powder alone or in the case where the average particle size of the large powder was 6.5 times or less that of the small powder, the packing density was relatively low. On the contrary, the packing density could be increased by increasing the average particle size of the large powder as compared with that of the small powder. The test results shown in FIG. 7 clearly illustrate this phenomenon.

Referring to FIG. 7, it can be seen that as compared with the case of using only the large powder, the packing density increases when both the large powder and the small powder are used together. Further, referring to FIG. 7, it can be seen that as a difference in average particle size between the large powder and the small powder increases, the packing density increases.

Further, referring to FIG. 8, which shows the variation of the dielectric constant depending on the average particle size of the large powder with the average particle size and volume fraction of the small powder fixed to 30 nm and 0.25, respectively, it can be seen that the larger the average particle size of the large powder, the higher the dielectric constant. Particularly, when the large powder has an average particle size of 500 nm and a volume fraction of 0.75, and the small powder has an average particle size of 30 nm, the dielectric constant reaches the highest value.

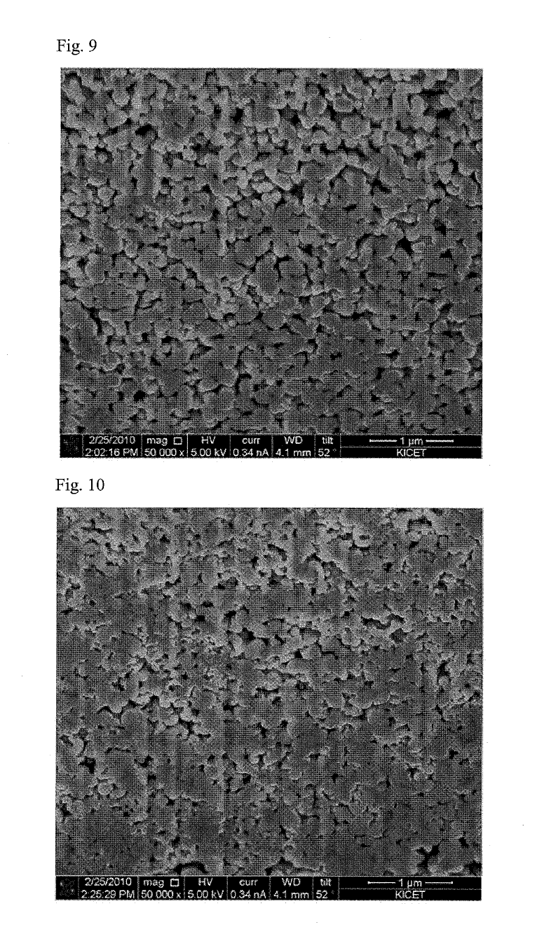

FIG. 9 is a micrograph of an insulator of an MIM capacitor manufactured using only large powder having an average particle size of 150 nm as the highly dielectric ceramic powder. FIG. 10 is a micrograph of an insulator of an MIM capacitor manufactured using 75 vol % of large powder having an average particle size of 150 nm and 25 vol % of small powder having an average particle size of 30 nm as the highly dielectric ceramic powder.

Referring to FIGS. 9 and 10, it can be seen that as compared with the case where only the large powder is used, the rate of filling the voids is higher when both the large powder and the small powder are used together. However, in both cases shown in FIGS. 9 and 10, the voids are not efficiently filled with the large powder.

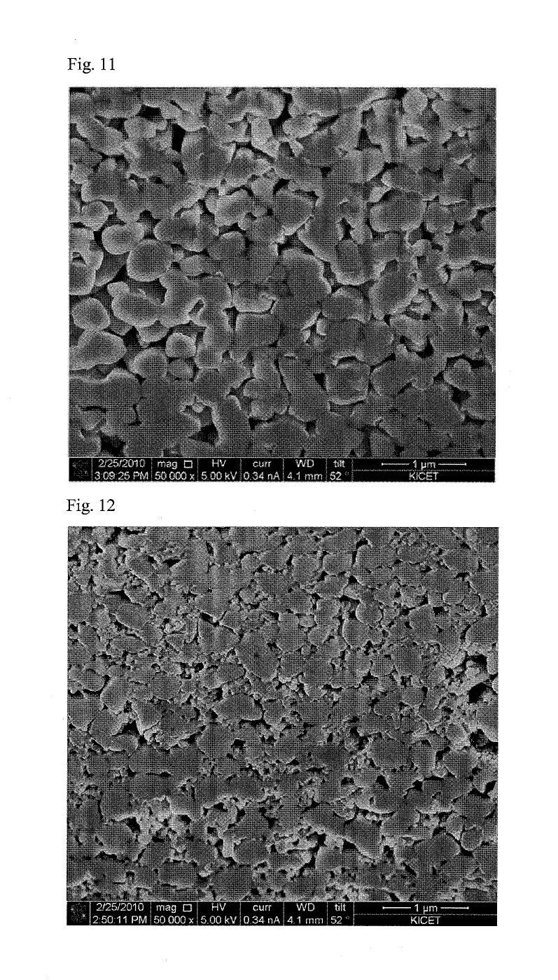

FIG. 11 is a micrograph of an insulator of an MIM capacitor manufactured using only large powder having an average particle size of 300 nm as the highly dielectric ceramic powder. FIG. 12 is a micrograph of an insulator of an MIM capacitor manufactured using 75 vol % of large powder having an average particle size of 300 nm and 25 vol % of small powder having an average particle size of 30 nm as the highly dielectric ceramic powder.

Referring to FIGS. 11 and 12, it can be seen that as compared with the case where only the large powder is used, the rate of filling the voids is higher when both the large powder and the small powder are used together. Further, when comparing FIG. 12 with FIG. 10, it can be seen that, as a difference in average particle size between the large powder and the small powder increases, the voids between the powders can be more efficiently filled with the powders.

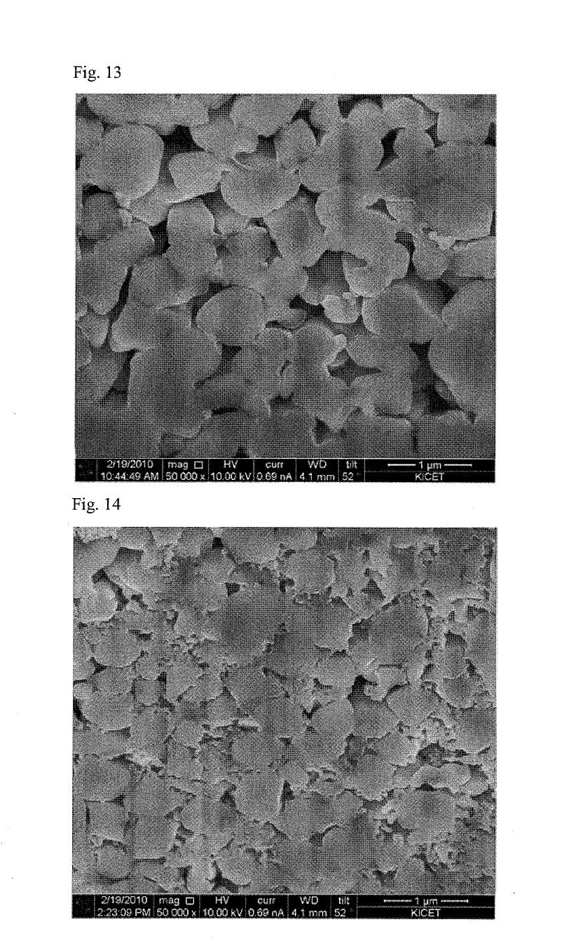

FIG. 13 is a micrograph of an insulator of an MIM capacitor manufactured using only large powder having an average particle size of 500 nm. FIG. 14 is a micrograph of an insulator of an MIM capacitor manufactured using 75 vol % of large powder having an average particle size of 500 nm and 25 vol % of small powder having an average particle size of 30 nm.

Referring to FIGS. 13 and 14, it can be seen that as compared with the case where only the large powder is used, the rate of filling the voids is higher when both the large powder and the small powder are used together. Further, when comparing FIG. 14 with FIGS. 10 and 12, it can be seen that, as a difference in average particle size between the large powder and the small powder increases, the voids between the powders can be more efficiently filled with the powders.

Considering these results, it is desirable that the highly dielectric ceramic powder comprising large powder and small powder to satisfy all of the following conditions relating to the average particle size and the volume fraction be applied to the insulator of the MIM capacitor. For the average particle size condition, the large powder has an average particle size of about 490˜510 nm, and the small powder has an average particle size of about 25˜35 nm. Further, for the volume fraction condition, the large powder has a volume fraction of about 70˜80 vol % and the small powder has a volume fraction of about 20˜30 vol %.

The MIM capacitor manufactured by the embodiment shown in FIG. 1 or 2 or by other methods includes the lower metal-insulator-upper metal structure.

For the MIM capacitor according to the invention, the insulator is formed of the highly dielectric ceramic powder having the polymer resin impregnated therein.

As described previously, when the polymer resin is contained in an amount of 10˜150 parts by weight with respect to 100 parts by weight of the highly dielectric ceramic powder, it is possible to obtain a sufficient effect of polymer impregnation without deteriorating the dielectric characteristics.

Here, the highly dielectric ceramic powder may comprise small powder and large powder having a larger particle size than the small powder. The small powder may be added in an amount of 20˜30 vol % and the large powder may be added in an amount of 70˜80 vol %.

Further, when the average particle size of the large powder is 6.5 times or more that of the small powder, the insulator may have a high dielectric constant. Specifically, the large powder may have an average particle size of 490˜510 nm and the small powder may have an average particle size of 25˜35 nm.

Further, as the average particle size of the highly dielectric ceramic powder increases, the dielectric constant also increases. Thus, considering the dielectric constant and the application of ink-jet printing, the highly dielectric ceramic powder may have an average particle size of 400˜800 nm.

In the MIM capacitor, the highly dielectric ceramic powder may comprise BaTiO₃. Further, in the insulator of the MIM capacitor, the polymer resin may be a thermocurable resin or a photocurable resin. Further, the lower and upper metals of the MIM capacitor may be formed of silver (Ag).

In the method according to the embodiments, the insulator is formed using a highly dielectric ceramic powder and a polymer resin by ink jet printing or the like without sintering. Thus, the method can reduce manufacturing costs while solving the problems relating to volume shrinkage and brittleness of ceramic per se.

Further, the non-sintered MIM capacitor according to the embodiments employs highly dielectric ceramic powders having different average particle sizes in a proper ratio. Thus, the non-sintered MIM capacitor has improved packing density, which leads to an effect of increasing the dielectric constant. As a result, it is possible to provide a capacitor having high performance.

Although some embodiments have been provided to illustrate the invention in conjunction with the drawings, it will be apparent to those skilled in the art that the embodiments are given by way of illustration only, and that that various modifications, changes, alterations, and equivalent embodiments can be made without departing from the spirit and scope of the invention. The scope of the invention should be limited only by the accompanying claims.

What is claimed is:

1. A method of manufacturing a non-sintered MIM capacitor comprising a lower metal-insulator-upper metal structure,
wherein the insulator is formed by a non-sintering process comprising:
preparing a ceramic-polymer composition comprising a highly dielectric ceramic powder, a polymer resin, and a solvent, the highly dielectric ceramic powder comprising small powder and large powder having a larger average particle size than the small powder;
forming a ceramic-polymer film by depositing the ceramic-polymer composition on the lower metal; and
curing the polymer resin in the ceramic-polymer film.

2. The method according to claim 1, wherein the ceramic-polymer composition is deposited by ink-jet printing.

3. The method according to claim 1, wherein the average particle size of the large powder is 6.5 times or more that of the small powder.

4. The method according to claim 1, wherein the highly dielectric ceramic powder comprises 20˜30 vol % of the small powder and 70˜80 vol % of the large powder.

5. The method according to claim 1, wherein the highly dielectric ceramic powder comprises 20˜30 vol % of the small powder and 70˜80 vol % of the large powder, and the average particle size of the large powder is 6.5 times or more that of the small powder.

6. The method according to claim 5, wherein the large powder has an average particle size of 490˜510 nm, and the small powder has an average particle size of 25˜35 nm.

7. The method according to claim 1, wherein the highly dielectric ceramic powder comprises BaTiO₃.

8. The method according to claim 1, wherein the polymer resin is contained in an amount of 10˜150 parts by weight with respect to 100 parts by weight of the highly dielectric ceramic powder.

9. The method according to claim 1, wherein the polymer resin is a thermocurable resin or a photocurable resin.

10. The method according to claim 1, wherein the ceramic-polymer composition further comprises a dispersant comprising at least one selected from a non-ionic surfactant, an anionic surfactant, a cationic surfactant, octyl-alcohol and acrylic polymer.

11. The method according to claim 10, wherein the dispersant is contained in an amount of 5 parts by weight or less with respect to 100 parts by weight of the ceramic-polymer composition.

12. A method of manufacturing a non-sintered MIM capacitor comprising a lower metal-insulator-upper metal structure,
wherein the insulator is fixated by a non-sintering process comprising:
preparing a ceramic composition comprising a highly dielectric ceramic powder and a solvent, the highly dielectric ceramic powder comprising small powder and large powder having a larger average particle size than the small powder;
preparing a polymer composition comprising a polymer resin and a solvent;
forming a ceramic film by depositing the ceramic composition on the lower metal;
forming a ceramic-polymer film by depositing the polymer composition on the ceramic film and penetrating the polymer composition into the ceramic film; and
curing the polymer resin in the ceramic-polymer film.

13. A method of manufacturing a non-sintered MIM capacitor comprising a lower metal-insulator-upper metal structure,
wherein the insulator is formed by a non-sintering process comprising:
preparing a ceramic-polymer composition comprising a highly dielectric ceramic powder, a polymer resin, and a solvent, the highly dielectric ceramic powder having an average particle size of 400 nm˜800 nm;
forming a ceramic-polymer film by depositing the ceramic-polymer composition on the lower metal; and
curing the polymer resin in the ceramic-polymer film.

14. A method of manufacturing a non-sintered MIM capacitor comprising a lower metal-insulator-upper metal structure,
wherein the insulator is formed by a non-sintering process comprising:
preparing a ceramic composition comprising a highly dielectric ceramic powder and a solvent, the highly dielectric ceramic powder having an average particle size of 400 nm˜800 nm;
preparing a polymer composition comprising a polymer resin and a solvent;
forming a ceramic film by depositing the ceramic composition on the lower metal;
forming a ceramic-polymer film by depositing the polymer composition on the ceramic film and penetrating the polymer composition into the ceramic film; and
curing the polymer resin in the ceramic-polymer film.

15. A non-sintered MIM capacitor comprising a lower metal-insulator-upper metal structure,
wherein the insulator is formed of a highly dielectric ceramic powder having a polymer resin impregnated therein, the highly dielectric ceramic powder comprising small powder and large powder having a larger average particle size than the small powder.

16. The non-sintered MIM capacitor according to claim 15, wherein the polymer resin is contained in an amount of 10˜150 parts by weight with respect to 100 parts by weight of the highly dielectric ceramic powder.

17. The non-sintered MIM capacitor according to claim 15, wherein the average particle size of the large powder is 6.5 times or more that of the small powder.

18. The non-sintered MIM capacitor according to claim 15, wherein the highly dielectric ceramic powder comprises 20˜30 vol % of the small powder and 70˜80 vol % of the large powder.

19. The non-sintered MIM capacitor according to claim 15, wherein the highly dielectric ceramic powder comprises 20˜30 vol % of the small powder and 70˜80 vol % of the large powder, and the average particle size of the large powder is 6.5 times or more that of the small powder.

20. A non-sintered MIM capacitor comprising a lower metal-insulator-upper metal structure,
wherein the insulator is formed of a highly dielectric ceramic powder having a polymer resin impregnated therein, the highly dielectric ceramic powder having an average particle size of 400 nm˜800 nm.
